(19) United States
(12) Patent Application Publication
(10) Pub. No.: US 2026/0157060 A1
(43) Pub. Date: Jun. 4, 2026

(54) ELECTRONIC DEVICE

(71) Applicant: Samsung Display Co., LTD., Yongin-si (KR)

(72) Inventors: SANGHOON KIM, Yongin-si (KR); TAEHYEOG JUNG, Yongin-si (KR); BYUNGHOON KANG, Yongin-si (KR); JINGYU SIM, Yongin-si (KR); HYUNJI LEE, Yongin-si (KR); SEONGJIN HWANG, Yongin-si (KR)

(21) Appl. No.: 19/258,330

(22) Filed: Jul. 2, 2025

(30) Foreign Application Priority Data
Aug. 12, 2024 (KR) 10-2024-0107628

(51) Int. Cl. H10K 59/131

(52) U.S. Cl. CPC H10K 59/131

(57) ABSTRACT

An electronic device includes a display panel including a folding area defined therein. The folding area includes first and second non-folding areas defined therein and spaced apart from each other with the folding area interposed therebetween and including pixels and signal lines connected to the pixels. A plate is disposed under the display panel and includes a pattern portion overlapping the folding area, a first flat portion overlapping the first non-folding area, and a second flat portion overlapping the second non-folding area. The plate is provided with first holes defined through an upper surface and a rear surface thereof. First lines a redisposed in the first holes and are connected to the signal lines, and a circuit board is connected to the signal lines via the first lines and is disposed under the plate.

This application claims priority to Korean Patent Application No. 10-2024-0107628, filed on Aug. 12, 2024, and all the benefits accruing therefrom under 35 U.S.C. § 119, the content of which in its entirety is herein incorporated by reference.

### BACKGROUND

### 1. Field

The present disclosure relates to a flexible electronic device. More particularly, the present disclosure relates to an electronic device including a driving circuit placed on a rear surface thereof to reduce a non-display area and preventing a crack from occurring when folded.

### 2. Description of Related Art

Various types of electronic devices, such as television sets, mobile phones, tablet computers, game units, or the like, are being developed. Recently, flexible electronic devices including a flexible display panel that is slidable or foldable are being developed.

Components included in the flexible electronic device are required to be designed appropriately to implement folding characteristics of the electronic device. However, different from an electronic device including a flat display panel, when the flexible electronic device is folded or slid, some of the components stacked one on another may become decoupled or cracked.

### SUMMARY

The present disclosure provides an electronic device capable of preventing components thereof from being decoupled or cracked when folded.

The present disclosure provides an electronic device capable of reducing a non-display area thereof.

Embodiments of the inventive concept provide an electronic device including a display panel including a folding area defined therein and first and second non-folding areas defined therein and spaced apart from each other with the folding area interposed therebetween and including pixels and signal lines connected to the pixels, a plate disposed under the display panel and including a pattern portion overlapping the folding area, a first flat portion overlapping the first non-folding area, and a second flat portion overlapping the second non-folding area and provided with first holes defined through an upper surface and a rear surface thereof, first lines disposed in the first holes and connected to the signal lines, and a circuit board connected to the signal lines via the first lines and disposed under the plate.

The plate is non-conductive and includes a glass material.

The plate has a thickness equal to or greater than about 70 micrometers (um) and equal to or smaller than about 400 micrometers.

The display panel further includes a base substrate that includes polyimide (PI) and is provided with second holes defined through upper and rear surfaces thereof and overlapping the first holes.

The display panel further includes second lines disposed in the second holes.

Each of the first lines further includes a first-first pad exposed without being covered by the rear surface of the plate and a first-second pad exposed without being covered by the upper surface of the plate.

Each of the second lines further includes a second-first pad exposed without being covered by the rear surface of the base substrate and a second-second pad exposed without being covered by the upper surface of the base substrate.

The electronic device further includes a first conductive film disposed between the circuit board and the plate and a second conductive film disposed between the plate and the base substrate.

One ends of the signal lines are connected to the pixels, the other ends of the signal lines are connected to the second lines, and the signal lines are connected to the circuit board via the second lines and the first lines.

Each of the first holes has a width equal to or greater than about 10 micrometers and equal to or smaller than about 100 micrometers when viewed in a cross-section.

The electronic device further includes a resin layer disposed between the plate and the display panel and including a first resin having a modulus equal to or greater than about 1 megapascals (MPa) and equal to or smaller than about 5 gigapascals (Gpa).

The resin layer has a thickness equal to or greater than about 5 micrometers and equal to or smaller than about 20 micrometers.

The display panel further includes a base substrate, and the base substrate includes a protrusion portion protruding outward by about 0.01 mm or more and about 1 mm or less with respect to an end of the resin layer, which is adjacent to the first holes, and an overlap portion extending inward from the protrusion portion and overlapping the resin layer.

The electronic device further includes an adhesive layer disposed between the circuit board and the plate and including a pressure sensitive adhesive material. The circuit board is attached to the rear surface of the plate by the adhesive layer.

The pattern portion includes a groove pattern defined by recessing a portion of the upper surface and at least a portion of the rear surface.

The plate further includes a resin portion filled in the groove pattern and including a second resin, and the pattern portion has a modulus equal to or greater than about 10 MPa and equal to or smaller than about 1 GPa.

The groove pattern is defined in plural, and at least a portion of the groove patterns is defined to completely penetrate through the upper and rear surfaces of the plate.

The groove pattern is defined by a groove flat portion and groove inclination portions spaced apart from each other and inclined in a direction toward the groove flat portion.

The groove pattern is defined through the upper and rear surfaces, and a side surface of the plate, which defines the groove pattern when viewed in a cross-section, has a tapered shape that becomes gradually narrower from the rear surface to the upper surface.

The circuit board includes a substrate film and a driving circuit disposed on the substrate film.

The electronic device further includes a ultra-thin glass layer disposed on the display panel and a protective layer disposed on the ultra-thin glass layer.

The electronic device further includes an impact absorbing layer disposed between the ultra-thin glass layer and the display panel and including polyethylene terephthalate (PET).

The plate has a thickness greater than a thickness of the display panel, and the pattern portion has a modulus equal to or greater than about 20 MPa and equal to or smaller than about 1 GPa.

According to the above, the electronic device includes the plate including the pattern portion and the adhesive layer coupling the plate to the display panel and prevents components of the display module from being decoupled or cracked.

According to the above, the driving circuit to drive the display module is placed at the rear surface of the display module, and thus, a non-display area of the display module is reduced.

### BRIEF DESCRIPTION OF THE DRAWINGS

The above and other advantages of the present disclosure will become readily apparent by reference to the following detailed description when considered in conjunction with the accompanying drawings wherein:

FIGS. 1A to 1B are perspective views of an electronic device according to an embodiment of the present disclosure;

FIG. 1C is a plan view of an electronic device according to an embodiment of the present disclosure;

FIG. 1D is perspective view an electronic device according to an embodiment of the present disclosure;

FIGS. 2A to 2C are perspective views of an electronic device according to an embodiment of the present disclosure;

FIG. 3 is an exploded perspective view of the electronic device according to an embodiment of the present disclosure;

FIG. 4 is a cross-sectional view of a display module according to an embodiment of the present disclosure;

FIG. 5 is a plan view of a display panel according to an embodiment of the present disclosure;

FIG. 6 is a cross-sectional view of a portion of a display panel according to an embodiment of the present disclosure;

FIG. 7 is a cross-sectional view of a portion of a display module taken along a line I-I′ of FIG. 5;

FIG. 8 is an enlarged view of an area AA′ of FIG. 7;

FIG. 9 is a cross-sectional view of a portion of a display module taken along a line II-II′ of FIG. 5;

FIG. 10 is a cross-sectional view of a folded state of a display module according to an embodiment of the present disclosure; and

FIGS. 11 to 14 are cross-sectional views of pattern portions included in a display module according to embodiments of the present disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

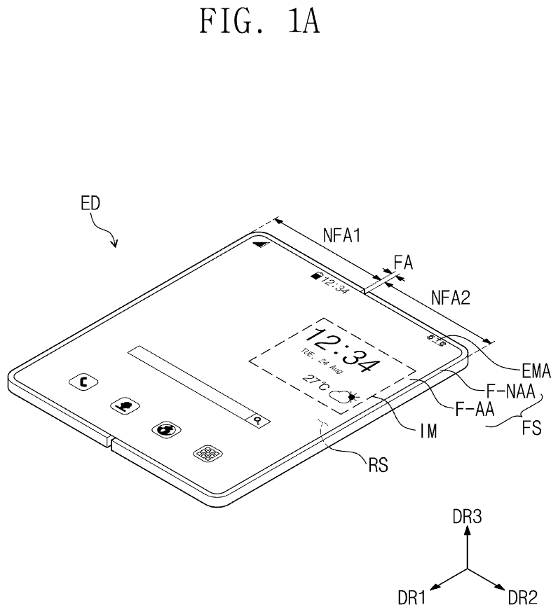

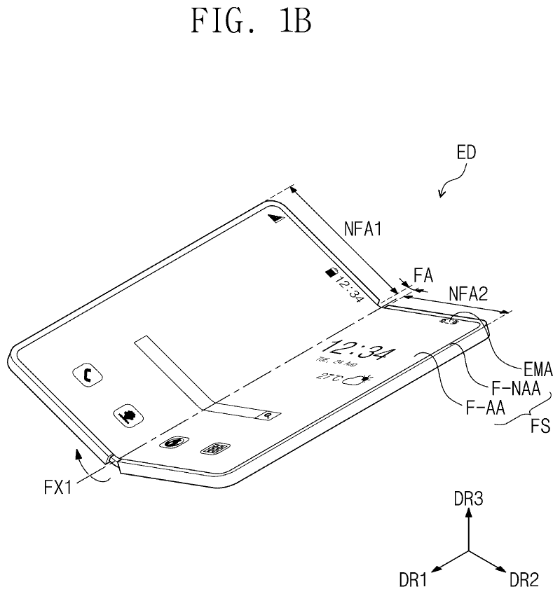

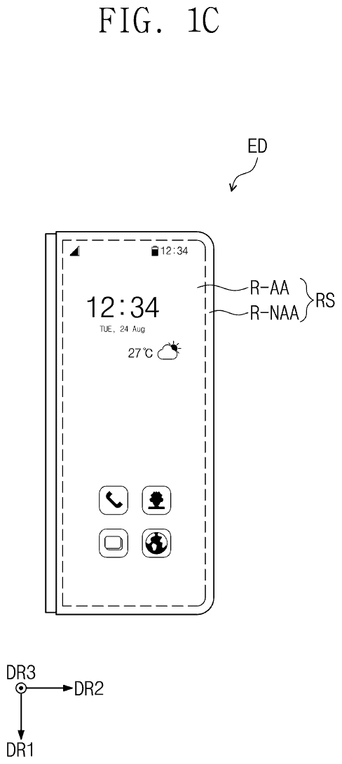

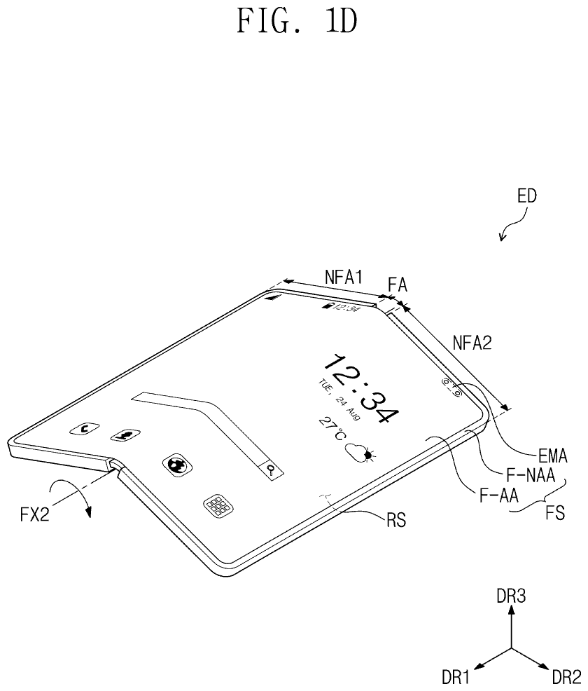

FIG. 1A is a perspective view of an electronic device ED according to an embodiment of the present disclosure.

FIG. 1A is a perspective view of the electronic device ED in an unfolded state according to an embodiment of the present disclosure. The electronic device ED may be a device that is activated in response to electrical signals. As an example, the electronic device ED may be a mobile phone, a tablet computer, a car navigation unit, a game unit, or a wearable device, however, it should not be limited thereto or thereby. FIG. 1A shows a foldable electronic device ED as a representative example. In the present embodiment, the mobile phone is shown as a representative example of the foldable electronic device ED.

The electronic device ED may include a first display surface FS defined by a first direction DR1 and a second direction DR2 intersecting the first direction DR1. The electronic device ED may provide an image IM to a user through the first display surface FS. The electronic device ED may display the image IM through the first display surface FS, which is substantially parallel to each of the first direction DR1 and the second direction DR2, toward a third direction DR3.

In the present disclosure, the first direction DR1 may be perpendicular to the second direction DR2, and a third direction DR3 may be a normal line direction with respect to the plane defined by the first direction DR1 and the second direction DR2. A thickness direction of the electronic device ED may be substantially parallel to the third direction DR3. A front surface (or upper surface) and a rear surface (or lower surface) may be opposite to each other in the third direction DR3, and a normal line direction of each of the front surface (or upper surface) and the rear surface (or lower surface) may be substantially parallel to the third direction DR3.

The front surface (or upper surface) may indicate a surface relatively closer to the first display surface FS, and the rear surface (or lower surface) may indicate a surface relatively far away from the first display surface FS. In addition, the rear surface (or lower surface) may indicate the surface restively closer to a second display surface RS described later. An upper side (or upper portion) may indicate a direction approaching the first display surface FS, and a lower side (or lower portion) may indicate a direction away from the first display surface FS.

A cross-section of each component refers to a flat surface parallel to the thickness direction DR3, and a plane of each component refers to a flat surface perpendicular to the thickness direction DR3. The plane refers to a flat surface defined by the first direction DR1 and the second direction DR2.

The electronic device ED may sense an external input applied thereto from an outside thereof. The external input may include various forms of inputs provided from the outside of the electronic device ED. For example, the external inputs may include a proximity input (e.g., hovering) applied when approaching close to or adjacent to the electronic device ED at a predetermined distance as well as a touch input by a user's body (e.g., user's hand). In addition, the external inputs may be provided in the form of force, pressure, temperature, light, etc.

The electronic device ED may include the first display surface FS and the second display surface RS. The first display surface FS may include a first active area F-AA, a first peripheral area F-NAA, and an electronic module area EMA. The second display surface RS may be opposite to at least a portion of the first display surface FS. That is, the second display surface RS may be defined as a portion of a rear surface of the electronic device ED.

The first active area F-AA may be activated in response to the electrical signals. The electronic device ED may display the image IM through the first active area F-AA, and various external inputs may be sensed through the first active area F-AA.

The image IM may not be displayed through the first peripheral area F-NAA. The first peripheral area F-NAA may be defined adjacent to the first active area F-AA. The first peripheral area F-NAA may have a predetermined color. The first peripheral area F-NAA may surround the first active area F-AA. Accordingly, the first active area F-AA may have a shape that is substantially defined by the first peripheral area F-NAA, however, this is merely one example. The first peripheral area F-NAA may be defined adjacent to only one side of the first active area F-AA or may be omitted.

Various electronic modules may be disposed in the electronic module area EMA. For example, the electronic module may include at least one of a camera, a speaker, an optical sensor, and a thermal sensor. An external object may be sensed through the electronic module area EMA of the first display surface FS or the second display surface RS, or a sound signal, such as a voice, may be provided to the outside through the electronic module area EMA of the first display surface FS or the second display surface RS. In addition, the electronic module may include a plurality of components, however, it should not be limited to a particular embodiment.

The electronic module area EMA may be surrounded by the first peripheral area F-NAA, however, it should not be limited thereto or thereby. As an example, the electronic module area EMA may be surrounded by the first active area F-AA and the first peripheral area F-NAA, and the electronic module area EMA may be defined in the first active area F-AA.

The electronic device ED may include at least one folding area FA and a plurality of non-folding areas NFA1 and NFA2 extending from the folding area FA. As an example, a first non-folding area NFA1, the folding area FA, and a second non-folding area NFA2 may be sequentially defined along the second direction DR2.

The second non-folding area NFA2 may be spaced apart from the first non-folding area NFA1 in the second direction DR2 with the folding area FA interposed therebetween. For example, the first non-folding area NFA1 may be disposed adjacent to one side of the folding area FA in the second direction DR2, and the second non-folding area NFA2 may be disposed adjacent to the other side of the folding area FA in the second direction DR2.

FIG. 1A shows the structure in which the electronic device ED includes one folding area FA as a representative example, however, the present disclosure should not be limited thereto or thereby, and the electronic device ED may include a plurality of folding areas defined therein. As an example, the electronic device may include two or more folding areas and three or more non-folding areas arranged with the folding area interposed therebetween.

FIG. 1B is a perspective view of a folding operation of the electronic device ED according to an embodiment of the present disclosure. FIG. 1C is a plan view of the electronic device ED in a folded state according to an embodiment of the present disclosure. FIG. 1D is a perspective view of a folding operation of the electronic device ED according to an embodiment of the present disclosure.

Referring to FIG. 1B, the electronic device ED may be folded with respect to a first folding axis FX1 extending in the first direction DR1. When the electronic device ED is folded, the folding area FA may have a predetermined curvature and a radius of curvature. The electronic device ED may be inwardly folded (in-folding) with respect to the first folding axis FX1 to allow the first non-folding area NFA1 to face the second non-folding area NFA2 and the first display surface FS not to be exposed to the outside.

Referring to FIG. 1C, the second display surface RS may be viewed by the user when the electronic device ED is inwardly folded. In this case, the second display surface RS may include a second active area R-AA through which images are displayed. The second active area R-AA may be activated in response to electrical signals. The images may be displayed through the second active area R-AA, and various external inputs may be sensed through the second active area R-AA.

In addition, the second display surface RS may include a second peripheral area R-NAA. The second peripheral area R-NAA may be defined adjacent to the second active area R-AA. The second peripheral area R-NAA may have a predetermined color. The second peripheral area R-NAA may surround the second active area R-AA. Although not shown in figures, the electronic device ED may further include an electronic module area in which an electronic module including various components is disposed in the second display surface RS.

According to an embodiment, when the electronic device ED is inwardly folded, a distance between the first non-folding area NFA1 and the second non-folding area NFA2 may be smaller than the radius of the circle defined by the radius of curvature of the folding area FA. In this case, the folding area FA may be folded to have a dumbbell shape, and the distance between the first non-folding area NFA1 and the second non-folding area NFA2 may be reduced. Accordingly, the electronic device ED may be slimmed down in the folded state.

Referring to FIG. 1D, the electronic device ED may be folded with respect to a second folding axis FX2 extending in the first direction DR1. The electronic device ED may be outwardly folded (out-folding) with respect to the second folding axis FX2 to allow the first display surface FS to be exposed to the outside. The electronic device ED may be configured to repeat the unfolding operation and the in-folding operation or to repeat the unfolding operation and the out-folding operation, however, the present disclosure should not be limited thereto or thereby.

FIGS. 1A to 1D show the electronic device ED folded with respect to one folding axis FX1 or FX2, however, the number of the folding axes and the number of non-folding areas should not be particularly limited. As an example, the electronic device ED may be folded with respect to multiple folding axes to allow a portion of the first display surface FS to face another portion of the first display surface FS and a portion of the second display surface RS to face another portion of the second display surface RS. In addition, the first and second folding axes FX1 and FX2 are shown as being parallel to long sides of the electronic device ED in the above embodiments, however, the present disclosure should not be limited thereto or thereby. According to an embodiment, the first and second folding axes FX1 and FX2 may be substantially parallel to short sides of the electronic device ED.

In the electronic device ED, the first non-folding area NFA1 and the second non-folding area NFA2 may be defined as areas respectively including the display surfaces FS and RS parallel to the plane defined by the first direction DR1 and the second direction DR2 in the folded state as shown in FIG. 1D, and the folding area FA may be defined as an area between the first non-folding area NFA1 and the second non-folding area NFA2. The folding area FA may include a curved portion that has a predetermined curvature in the folded state.

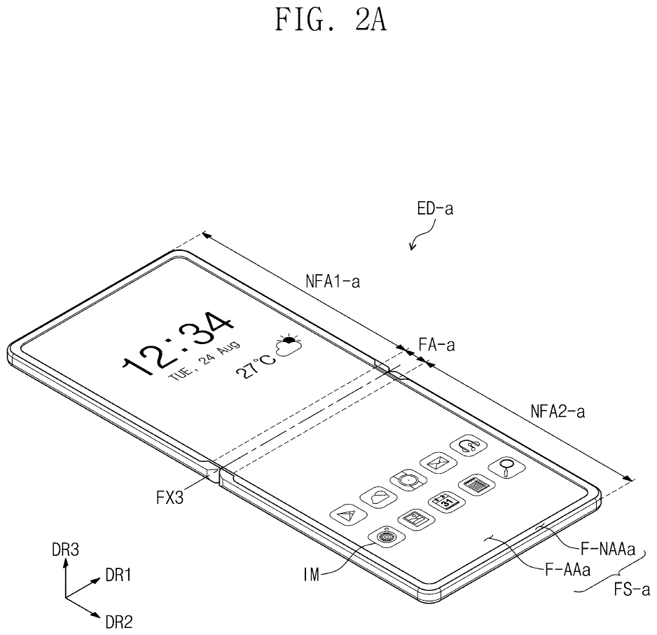

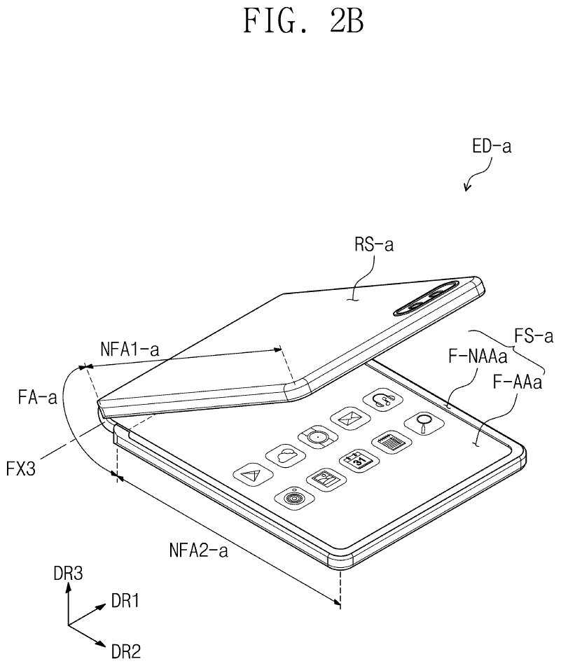

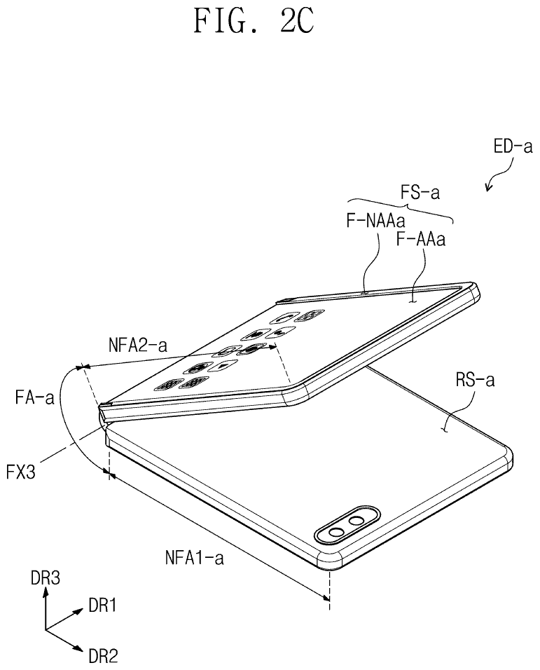

FIGS. 2A to 2C are perspective views of an electronic device ED-a.

FIG. 2A is a perspective view of the electronic device ED-a according to an embodiment of the present disclosure. FIG. 2A is a perspective view of the electronic device ED-a in an unfolding state. FIGS. 2B and 2C are perspective views illustrating a folding operation of the electronic device ED-a. FIG. 2B is a perspective view illustrating an in-folding operation of the electronic device ED-a shown in FIG. 2A. FIG. 2C is a perspective view illustrating an out-folding operation of the electronic device ED-a shown in FIG. 2A. FIG. 2B illustrates the electronic device ED-a in a first mode, and FIG. 2C illustrates the electronic device ED-a in a second mode.

Referring to FIG. 2A, the electronic device ED-a may be folded with respect to a third folding axis FX3 extending in a direction substantially parallel to the first direction DR1. The direction in which the third folding axis FX3 extends may be substantially parallel to a direction in which a short side of the electronic device ED-a extends.

The electronic device ED-a may include a folding area FA-a, a first non-folding area NFA1-a adjacent to one side of the folding area FA-a, and a second non-folding area NFA2-a adjacent to the other side of the folding area FA-a. The first non-folding area NFA1-a may be spaced apart from the second non-folding area NFA2-a with the folding area FA-a interposed therebetween.

The folding area FA-a may be folded with respect to the third folding axis FX3. When the electronic device ED-a is folded, the folding area FA-a may have a predetermined curvature and a radius of curvature. The electronic device ED-a may be inwardly folded (in-folding) to allow the first non-folding area NFA1-a to face the second non-folding area NFA2-a and a display surface FS-a not to be exposed to the outside.

Referring to FIG. 2A, the display surface FS-a may be viewed by the user when the electronic device ED-a is in an unfolding state. As described with reference to FIGS. 1A to 1D, the display surface FS-a of the electronic device ED-a may include an active area F-AAa and a peripheral area F-NAAa. One or more images IM may be displayed through the active area F-AAa, and various external inputs may be sensed through the active area F-AAa.

Referring to FIG. 2B, a rear surface RS-a may be viewed by the user when the electronic device ED-a is inwardly folded. As an example, the rear surface RS-a may function as a second display surface through which one or more images are displayed. In addition, the rear surface RS-a may include an electronic module area in which an electronic module including various components is disposed. An active area through which images are displayed may be further defined in the rear surface RS-a of the electronic device ED-a.

Referring to FIG. 2C, the electronic device ED-a may be folded with respect to the third folding axis FX3 to allow a portion of the rear surface RS-a, which overlaps the first non-folding area NFA1-a, to face another portion of the rear surface RS-a, which overlaps the second non-folding area NFA2-a.

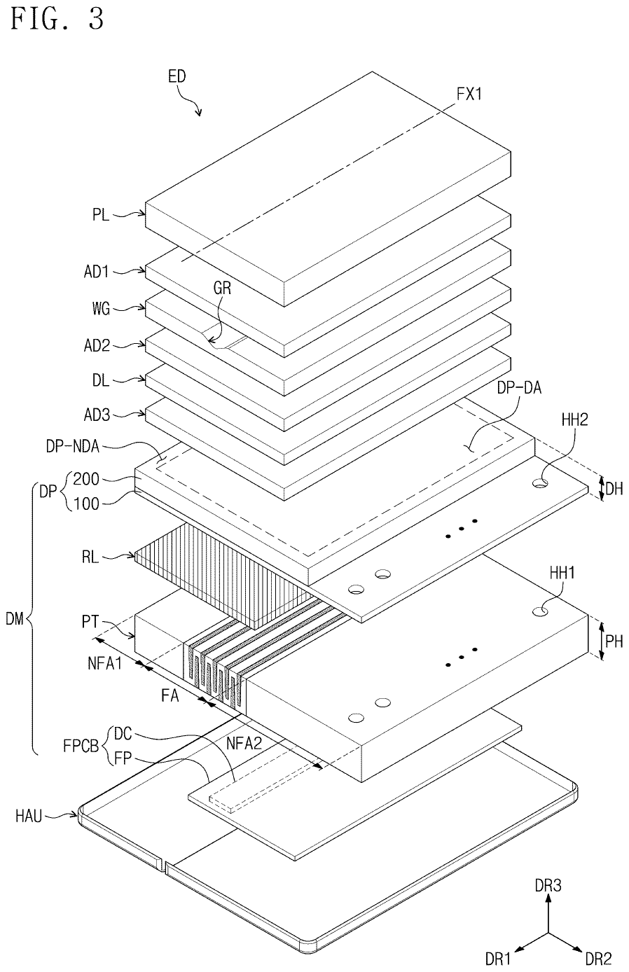

FIG. 3 is an exploded perspective view of the electronic device ED according to an embodiment of the present disclosure.

In FIG. 3 and the drawings below, when viewed in the plane, a size of the second non-folding area NFA2 is exaggerated to be larger than that of the first non-folding area NFA1 for the sake of clarity in explaining the components overlapping the second non-folding area NFA2, however, the present disclosure should not be limited thereto or thereby. As an example, the size of the first non-folding area NFA1 may be substantially the same as the size of the second non-folding area NFA2 when viewed in the plane.

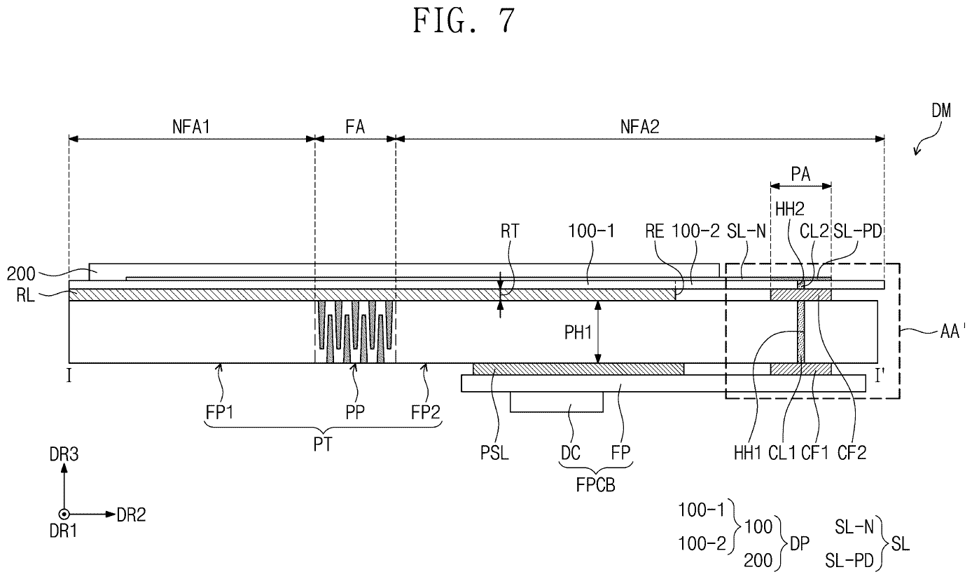

For the convenience of explanation, a signal line SL (refer to FIG. 7) and lines CL1 and CL2 (refer to FIG. 7) described later are omitted in FIG. 3. In addition, features described below for the electronic device ED may be applied to the electronic device ED-a described with reference to FIGS. 2A to 2C.

Referring to FIG. 3, the electronic device ED may include a window WG, a protective layer PL, an impact absorbing layer DL, a display module DM, and a housing HAU.

The window WG and the protective layer PL may be disposed above the display module DM. The window WG and the protective layer PL may be optically transparent. The image IM (refer to FIG. 1A) generated by the display module DM may be provided to the user after passing through the window WG and the protective layer PL.

The window WG may include a polymer substrate or a glass substrate. In the present embodiment, a portion of the window WG, which overlaps the folding area FA, may be etched, and thus, folding characteristics of the window WG may be improved. As shown in FIG. 3, the window WG may be provided with a window groove GR defined therein by etching an upper surface thereof, however, the present disclosure should not be limited thereto or thereby.

The protective layer PL may be disposed above the window WG. The protective layer PL may serve as a functional layer to protect an upper surface of the window WG. The protective layer PL may include a polymer film.

The impact absorbing layer DL may be disposed above the display module DM and may prevent the display module DM from being pressed and deformed by external impact and force.

The impact absorbing layer DL may include a flexible plastic material. As an example, the impact absorbing layer DL may include polyethylene terephthalate (PET).

The display module DM may be activated in response to electrical signals, and the activated display module DM may display the image IM (refer to FIG. 1A) through the first active area F-AA (refer to FIG. 1A) of the electronic device ED. The display module DM may include a display area DP-DA and a non-display area DP-NDA defined therein. The display area DP-DA may be activated in response to electrical signals. The non-display area DP-NDA may be defined adjacent to at least one side of the display area DP-DA.

The display module DM may include a display panel DP, a plate PT disposed under the display panel DP, a resin layer RL disposed between the display panel DP and the plate PT, and a circuit board FPCB disposed under the plate PT.

Although not shown in FIG. 3, the display module DM may further include an input sensing layer disposed on the display panel DP or an optical layer disposed between the display module DM and the window WG.

The display panel DP may have a configuration that substantially generates the image IM (refer to FIG. 1A). The display panel DP may include a first substrate 100 and a second substrate 200 disposed on the first substrate 100. The first substrate 100 may have a length longer than a length of the second substrate 200 in the second direction DR2.

The first substrate 100 may be provided with second holes HH2 defined through upper and rear surfaces thereof.

The plate PT may be disposed under the display panel DP. The plate PT may prevent a foreign substance from entering the display module DM.

In addition, the plate PT may include a pattern portion (refer to FIG. 7) overlapping the folding area and filled with a resin to facilitate the folding operation of the electronic device ED and flat portions FP1 and FP2 (refer to FIG. 7), and this will be described in detail later.

The plate PT may have a thickness PH greater than a thickness DH of the display panel DP. The plate PT may have the thickness PH equal to or greater than about 70 um and equal to or smaller than about 400 um. In detail, the plate PT may have the thickness PH equal to or greater than about 100 um and equal to or smaller than about 300 um.

The plate PT may include a glass material. Accordingly, the plate PT may be non-conductive and have improved processability. The plate PT may be provided with first holes HH1 defined therethrough to connect the display panel DP and the circuit board FPCB.

The resin layer RL may be disposed between the plate PT and the display panel DP. The resin layer RL may function to attach the plate PT to the display panel DP.

The resin layer RL may have a modulus equal to and greater than about 1 MPa and equal to or smaller than about 5 GPa and may include a first resin. As an example, the first resin may include an adhesive material such as a silicon-based adhesive material, an epoxy-based adhesive material, an acryl-based adhesive material. The resin layer RL may have a thickness RT equal to or greater than about 5 um and equal to or smaller than about 20 um.

The circuit board FPCB may be disposed on a rear surface of the plate PT. The circuit board FPCB may include a substrate film FP and a driving circuit DC.

The substrate film FP may receive and transmit electrical signals and may be connected to the driving circuit DC. In the present embodiment, the substrate film FP may be provided in the form of a flexible film. As an example, the substrate film FP may be provided in the form of a printed circuit board, however, the present disclosure should not be limited thereto or thereby. That is, the substrate film FP does not necessarily need to be bent and may be provided in a flat form with rigidity.

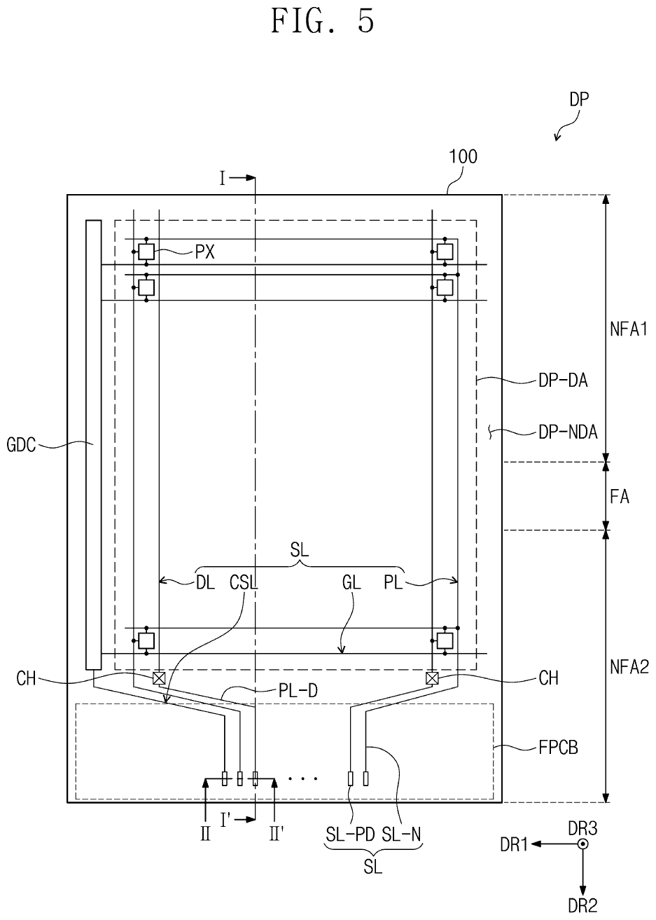

The driving circuit DC may be disposed on a rear surface of the substrate film FP. The driving circuit DC may transmit electrical signals to pixels PX (refer to FIG. 5) to drive the pixels PX. The driving circuit DC may be mounted on the rear surface of the substrate film FP in the form of a driving chip.

The housing HAU may be coupled with the window WG and the protective layer PL to define an exterior of the electronic device ED. The housing HAU may provide a predetermined accommodation space. The display module DM may be accommodated in the accommodation space and may be protected from external impacts. According to an embodiment, the housing HAU may further include a hinge structure disposed overlapping the folding area FA to guide the folding operation of the electronic device ED.

The housing HAU may include a material with relatively high rigidity. As an example, the housing HAU may include a plurality of frames and/or support plates formed of a glass, plastic, or metal material.

According to a conventional foldable electronic device, a plate disposed under a display panel is formed of a metal material to have a high modulus. Unlike the conventional foldable electronic device, the plate PT according to a non-limiting embodiment of the present disclosure may include the glass material. Due to the characteristics of the material, the plate PT formed of glass may be significantly lighter than the plate formed of metal, and its processibility may be improved.

For example, the first holes HH1 that penetrate the upper surface and the rear surface of the plate PT may be easily formed by a through-glass via (TGV) formation process, and thus, the circuit board FPCB may be connected to the display panel DP.

Accordingly, an arrangement structure of the circuit board FPCB of the display module DM may be changed. According to the display module DM of the present embodiment, since the circuit board FPCB may be disposed under the plate PT, the non-display area DP-NDA may be decreased, and display area DP-DA may be increased. Therefore, the user's usability and convenience may be improved.

In addition, according to the display module DM, the modulus of the resin layer RL and the plate PT may be optimized, thereby preventing a cracking and buckling phenomenon from occurring during the folding operation.

The electronic device ED according to the present embodiment may further include first, second, and third adhesive layers AD1, AD2, and AD3.

The first adhesive layer AD1 may be disposed between the window WG and the protective layer PL. The second adhesive layer AD2 may be disposed between the impact absorbing layer DL and the window WG. The third adhesive layer AD3 may be disposed between the display module DM and the impact absorbing layer DL.

Each of the first, second, and third adhesive layers AD1, AD2, and AD3 may include a conventional adhesive, such as a pressure sensitive adhesive (PSA), an optically clear adhesive (OCA), an optical clear resin (OCR), or the like, but it should not be particularly limited.

Although not shown separately, the electronic device ED may further include an ultra-thin glass layer disposed on the display panel DP and a protective layer disposed on the ultra-thin glass layer.

The electronic device ED may further include an impact absorbing layer disposed between the ultra-thin glass layer and the display panel DP and including polyethylene terephthalate (PET).

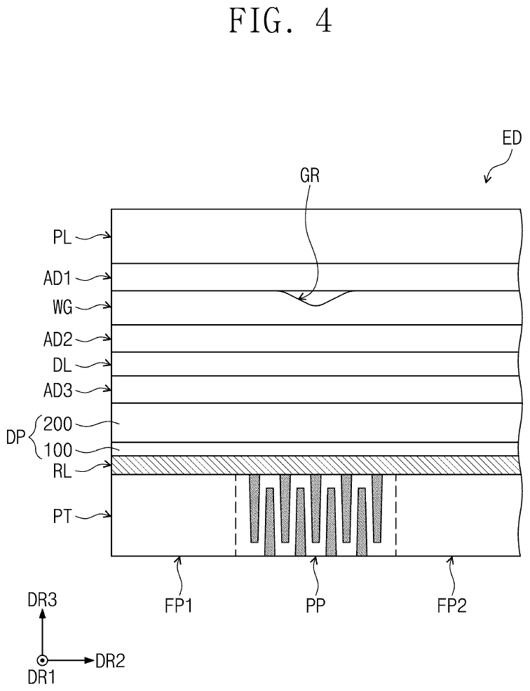

FIG. 4 shows a cross-section of a portion of the electronic device ED according to an embodiment of the present disclosure. For the convenience of explanation, the housing HAU (refer to FIG. 3) and the circuit board FPCB (refer to FIG. 3) are omitted in the electronic device ED shown in FIG. 4.

Tables 1 and 2 below are intended to explain allowable moduli of the plate PT included in the display module DM (refer to FIG. 3) according to embodiment examples 1 and 2 of the present disclosure, respectively.

Hereinafter, the allowable moduli of the plate PT included in the display module DM (refer to FIG. 3) will be described with reference to FIG. 4 and Tables 1 and 2. In the present disclosure, the term “permissible” refers to a state where, during the folding operation of the display module DM (refer to FIG. 3), no buckling occurs in at least one of the components included in the display module DM (refer to FIG. 3). In addition, it refers to a state where no irreversible changes in physical properties (e.g., cracks) occur in the display module DM (refer to FIG. 3).

Tables 1 and 2 show experimental results when the display module is folded at about 1.5 R and at about −20° C. In Tables 1 and 2, the term “NG” means that buckling occurs in at least one of the components included in the display module DM (refer to FIG. 3), and the term “OK” means that buckling does not occur in the components included in the display module DM (refer to FIG. 3). The term “RISK” means that buckling does not occur in the display module DM (refer to FIG. 3), but there is a possibility that buckling occurs.

In Tables 1 and 2, “B/P” may mean “backplane”.

TABLE 1

| Display | | Modulus of resin layer (RL) | | | | |
|---|---|---|---|---|---|---|
| module | | 1.4 GPa | | | | |
| condition | Modulus of pattern portion (PP) | 10 MPa | 100 MPa | 1 GPa | 1.5 GPa | 2 GPa |
| Curve | Protective layer (PL) | 1.77 | 1.79 | 1.77 | 1.77 | — |
| strain (%) | Window (WG) | 0.91 | 0.92 | 0.9 | 0.89 | — |
| | Encapsulation layer of display | 0.72 | 0.6 | −0.44 | −0.89 | — |
| | panel (DP) | | | | | |
| | B/P of display panel (DP) | 1.06 | 0.94 | −0.1 | −0.56 | — |
| | Resin layer (RL) | 2.68 | 2.58 | 1.54 | 1.06 | — |
| | Plate (PT) | 11.1 | 11.1 | 10.2 | 9.72 | — |

| | | | | | |
|---|---|---|---|---|---|
| Whether buckling occurs | RISK | OK | OK | RISK | NG |

The electronic device ED according to embodiment example 1 may include the plate PT, the resin layer RL, the display panel DP, the third adhesive layer AD3, the impact absorbing layer DL, the second adhesive layer AD2, the window WG, the first adhesive layer AD1, and the protective layer PL, which are sequentially stacked in the third direction DR3, as shown in FIG. 4. In addition, the components respectively have thicknesses of about 150 um, about 10 um, about 30 um, about 50 um, about 23 um, about 50 um, about 30 um, about 50 um, and about 70 um. Referring to Table 1, although the resin layer RL has a modulus of about 1.4 GPa in the module structure according to embodiment example 1, the electronic device may be folded when the pattern portion PP has the modulus of ranging from about 100 MPa to about 1 GPa.

However, when the pattern portion PP has the modulus of about 10 MPa, a curve strain occurring in the encapsulation layer is about 0.72%, and when the pattern portion PP has the modulus of about 1.5 GPa, the compressive strain occurring in the encapsulation layer is about-0.89%. When an absolute value of the compressive strain occurring in the encapsulation layer is equal to or greater than about 0.7%, it may indicate a risk of buckling in the electronic device ED.

In addition, when the pattern portion PP has the modulus of about 2 GPa, buckling occurs.

As described above, in the case of embodiment example 1, the reliability of the electronic device ED may be secured when the modulus of the pattern portion PP is in the range of about 10 MPa or more and about 1 GPa or less.

TABLE 2

| Display | | Modulus of resin layer (RL) | | | | |
|---|---|---|---|---|---|---|
| module | | 1.4 GPa | | | | |
| condition | Modulus of pattern portion (PP) | 10 MPa | 100 MPa | 1 GPa | 1.5 GPa | 2 GPa |
| Curve | Protective layer (PL) | 1.88 | 1.87 | 1.85 | 1.83 | — |
| strain (%) | Window (WG) | 0.99 | 0.98 | 0.94 | 0.92 | — |
| | Encapsulation layer of display | 0.55 | 0.43 | −0.61 | −1.06 | — |
| | panel (DP) | | | | | |
| | B/P of display panel (DP) | 0.91 | 0.79 | −0.26 | −0.72 | — |
| | Resin layer (RL) | 2.66 | 2.53 | 1.47 | 0.99 | — |
| | Plate (PT) | 11.7 | 11.6 | 10.6 | 10.1 | — |

| | | | | | |
|---|---|---|---|---|---|
| Whether buckling occurs | OK | OK | OK | RISK | NG |

The electronic device ED according to embodiment example 2 may include the plate PT, the resin layer RL, the display panel DP, the second adhesive layer AD2, the window WG, the first adhesive layer AD1, and the protective layer PL, which are sequentially stacked in the third direction DR3. That is, the third adhesive layer AD3 and the impact absorbing layer DL are omitted in the electronic device ED according to embodiment example 2 when compared to the electronic device ED shown in FIG. 4 according to embodiment example 1. In addition, the components of the electronic device ED according to embodiment example 2 respectively have thicknesses of about 150 um, about 10 um, about 30 um, about 50 um, about 30 um, about 50 um, and about 70 um. Referring to Table 2, although the resin layer RL has a modulus of about 1.4 GPa in the module structure according to embodiment example 2, the electronic device may be folded when the pattern portion PP has the modulus of about 10 MPa, about 100 MPa, or about 1 GPa.

However, when the pattern portion PP has the modulus of about 1.5 GPa, the curve strain occurring in the encapsulation layer of the display panel DP increases to about-1.06%. In addition, when the pattern portion PP has the modulus of about 2 GPa, buckling occurs.

As described above, in the case of embodiment example 2, the reliability of the electronic device ED may be secured when the modulus of the pattern portion PP is in the range of about 10 MPa or more and about 1 GPa or less.

In addition, according to the display module DM, as the resin layer RL having high modulus is disposed under the display panel DP, the display panel DP may be prevented from sagging due to gravity.

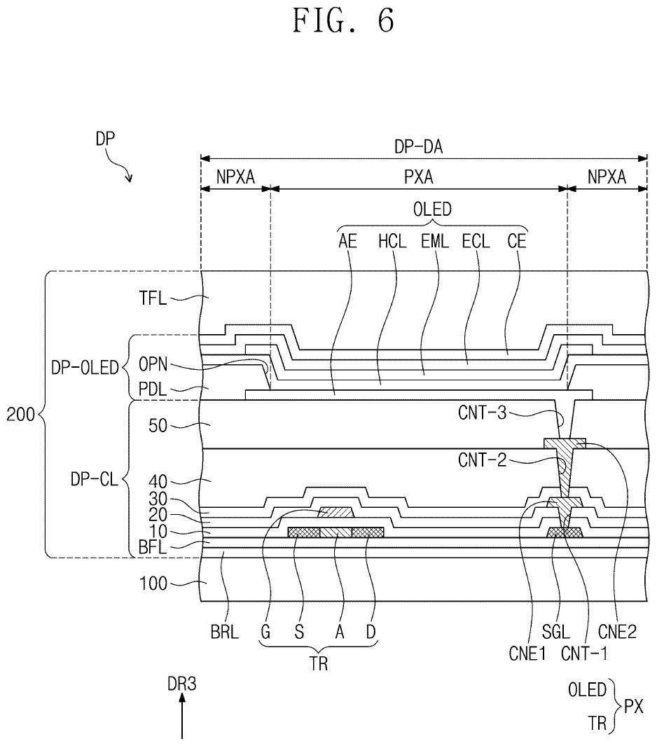

FIG. 5 is a plan view of the display panel DP according to an embodiment of the present disclosure. FIG. 6 is a cross-sectional view of a portion of the display panel DP according to an embodiment of the present disclosure. FIG. 6 shows a cross-section of the display panel DP corresponding to a light emitting area PXA and a portion of a non-light-emitting area NPXA.

Referring to FIG. 5, the display panel DP may include the pixels PX, a gate driving circuit GDC, and the signal lines SL.

The pixels PX may be arranged in the display area DP-DA. FIG. 5 shows a structure in which the pixels PX are arranged in the first and second directions DR1 and DR2 as a representative example. However, the arrangement of the pixels PX should not be limited thereto or thereby. As an example, the pixels PX may be arranged in the form of a pentile (PENTILE®).

Each of the pixels PX may include a light emitting element and a pixel driving circuit connected to the light emitting element. In the present embodiment, the light emitting element may be an organic light emitting element.

The gate driving circuit GDC may be disposed in the non-display area DP-NDA of the display panel DP. The gate driving circuit GDC may sequentially output gate signals to gate lines GL. The gate driving circuit GDC may be integrated in the display panel DP by an oxide silicon gate driver circuit (OSG) or amorphous silicon gate (ASG) driver circuit process.

The signal lines SL may be disposed in the display area DP-DA and the non-display area DP-NDA. The signal lines SL may include the gate lines GL, data lines DL, a power line PL, and a control signal line CSL.

Each of the gate lines GL may be connected to a corresponding pixel PX among the pixels PX, and each of the data lines DL may be connected to a corresponding pixel PX among the pixels PX. The power line PL may be connected to the pixels PX. The control signal line CSL may provide control signals to the gate driving circuit GDC.

The gate lines GL may extend in the first direction DR1 and may be arranged in the second direction DR2. The data lines DL may extend in the second direction DR2 and may be arranged in the first direction DR1. The data lines DL may be insulated from the gate lines GL while intersecting the gate lines GL.

Auxiliary signal lines PL-D may be arranged to overlap the non-display area NDA and may be connected to the data lines DL. The auxiliary signal lines PL-D connected to the data lines DL may be disposed on a different layer from the data lines DL. Each of the data lines DL may be electrically connected to a corresponding auxiliary signal line among the auxiliary signal lines PL-D through a contact hole CH.

The contact hole CH may penetrate through at least one insulating layer among insulating layers disposed between the data lines DL and the auxiliary signal lines PL-D. FIG. 5 shows two contact holes CH as a representative example, however, the present disclosure should not be limited thereto or thereby. According to an embodiment, the contact hole CH may be omitted. The data lines DL may be disposed on the same layer as the auxiliary signal lines PL-D.

In this case, one data line among the data lines DL and one auxiliary line among the auxiliary signal lines PL-D, which is connected to the one data line, may be defined as one signal line. The one data line and the one auxiliary signal line, which are connected to each other, may correspond to different portions of the one signal line.

Each of the signal lines SL may include a line part SL-N and a signal pad SL-PD. In the present embodiment, the line part SL-N may be provided integrally with the signal pad SL-PD, but they are distinguished for the sake of convenience in explanation. That is, an end portion of each signal line SL may be referred to as the signal pad SL-PD, however, the present disclosure should not be limited thereto or thereby. According to an embodiment, the signal pad SL-PD may be provided separately from the line part SL-N.

FIG. 5 shows a structure in which the signal pads SL-PD are arranged in one row along the first direction DR1 as a representative example, however, the arrangement of the signal pads SL-PD should not be limited thereto or thereby. As an example, the signal pads SL-PD may be arranged in a plurality of rows.

Referring to FIG. 6, the display panel DP may include the first substrate 100 and the second substrate 200.

The first substrate 100 may provide a base surface on which components of the display panel DP are disposed. The first substrate 100 may also be referred to as a base substrate. In the present embodiment, the base substrate 100 may include polyimide (PI).

The second substrate 200 may be disposed on the first substrate 100. The second substrate 200 may include a circuit element layer DP-CL, a display element layer DP-OLED disposed on the circuit element layer DP-CL, and an encapsulation layer TFL disposed on the display element layer DP-OLED.

For the convenience of explanation, FIG. 6 shows only one transistor TR as a representative example of the pixel driving circuit, however, the present disclosure should not be limited thereto or thereby. According to an embodiment, the pixel PX may include a plurality of transistors.

In the present embodiment, the circuit element layer DP-CL may include a barrier layer BRL, a buffer layer BFL, first, second, third, fourth, and fifth insulating layers 10, 20, 30, 40, and 50, the transistor TR, the signal line SL, a first connection electrode CNE1, and a second connection electrode CNE2, however, the present disclosure should not be limited thereto or thereby. The barrier layer BRL or the buffer layer BFL may be omitted, one or more layers of the first, second, third, fourth, and fifth insulating layers 10, 20, 30, 40, and 50 may be omitted, or the circuit element layer DP-CL may further include other insulating layers.

The barrier layer BRL may be disposed on the base substrate 100. The barrier layer BRL may prevent a foreign substance from entering from the outside. The barrier layer BRL may include a silicon oxide layer and a silicon nitride layer. Each of the silicon oxide layer and the silicon nitride layer may be provided in plural, and the silicon oxide layers may be alternately stacked with the silicon nitride layers.

The buffer layer BFL may be disposed on the barrier layer BRL. The buffer layer BFL may improve an adhesive force between a semiconductor pattern and the base substrate 100 or between a conductive pattern and the base substrate 100. The buffer layer BFL may include a silicon oxide layer and a silicon nitride layer. The silicon oxide layer and the silicon nitride layer may be alternately stacked with each other.

The semiconductor pattern may be disposed on the buffer layer BFL. The semiconductor pattern may include polycrystalline silicon, however, it should not be limited thereto or thereby. According to an embodiment, the semiconductor pattern may include an amorphous silicon or metal oxide.

The transistor TR may include a gate G connected to the gate line, an active A overlapping the gate G, a source S connected to the data line, and a drain D disposed spaced apart from the source S. The source S, the active A, and the drain D of the transistor TR may be formed from the semiconductor pattern.

The first insulating layer 10 may be disposed on the buffer layer BFL. The first insulating layer 10 may cover the semiconductor pattern. The first insulating layer 10 may commonly overlap the pixels. The gate G may be disposed on the first insulating layer 10. The gate G may be a portion of a metal pattern. The gate G may overlap the active A.

The second insulating layer 20 may be disposed on the first insulating layer 10 and may cover the gate G. The second insulating layer 20 may commonly overlap the pixels. Although not show in FIG. 6, an upper electrode may be disposed on the second insulating layer 20 to overlap the gate G. The first connection electrode CNE1 disposed on the second insulating layer 20 may be connected to the signal line SL via a contact hole CNT-1 defined through the first and second insulating layers 10 and 20.

The third insulating layer 30 may be disposed on the second insulating layer 20 to cover the upper electrode and the first connection electrode CNE1.

Each of the first to third insulating layers 10 to 30 may be an inorganic layer and/or an organic layer and may have a single-layer or multi-layer structure.

The fourth insulating layer 40 may be disposed on the third insulating layer 30. The second connection electrode CNE2 may be disposed on the fourth insulating layer 40. The second connection electrode CNE2 may be connected to the first connection electrode CNE1 via a contact hole CNT-2 defined through the third and fourth insulating layers 30 and 40.

The fifth insulating layer 50 may be disposed on the fourth insulating layer 40 and may cover the second connection electrode CNE2. The fifth insulating layer 50 may be an organic layer. A first electrode AE may be disposed on the fifth insulating layer 50. The first electrode AE may be connected to the second connection electrode CNE2 via a contact hole CNT-3 defined through the fifth insulating layer 50.

The display element layer DP-OLED may include a pixel definition layer PDL and a light emitting element OLED. A pixel opening OPN may be defined through the pixel definition layer PDL. At least a portion of the first electrode AE may be exposed through the pixel opening OPN of the pixel definition layer PDL. In the present embodiment, the light emitting area PXA may be defined to correspond to the portion of the first electrode AE exposed through the pixel opening OPN.

A hole control layer HCL may be commonly disposed over the light emitting area PXA and the non-light emitting area NPXA. The hole control layer HCL may include a hole transport layer and may further include a hole injection layer.

A light emitting layer EML may be disposed on the hole control layer HCL. The light emitting layer EML may be disposed in an area corresponding to the pixel opening OPN. That is, the light emitting layer EML may be disposed in each of the pixels after being separated into portions, however, the present disclosure should not be limited thereto or thereby. According to an embodiment, the light emitting layer EML may be commonly formed over the pixels PX using an open mask.

An electron control layer ECL may be disposed on the light emitting layer EML. The electron control layer ECL may include an electron transport layer and may further include an electron injection layer. The hole control layer HCL and the electron control layer ECL may be commonly formed in the pixels using the open mask.

A second electrode CE may be disposed on the electron control layer ECL. The second electrode CE may have an integral shape and may be commonly disposed over the pixels.

The encapsulation layer TFL may be disposed on the second electrode CE. The encapsulation layer TFL may include a plurality of thin layers. The encapsulation layer TFL may prevent moisture and oxygen from entering the display element layer DP-OLED.

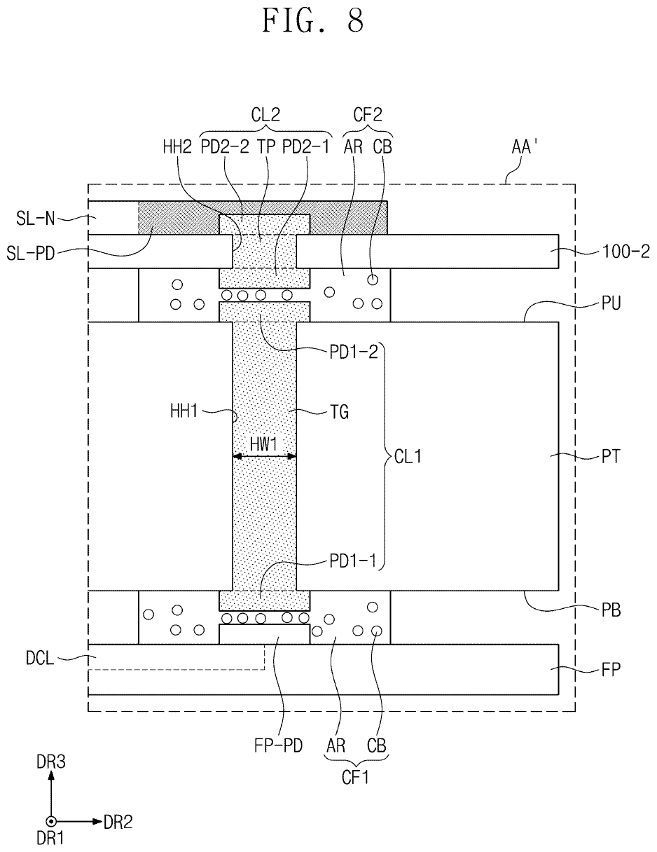

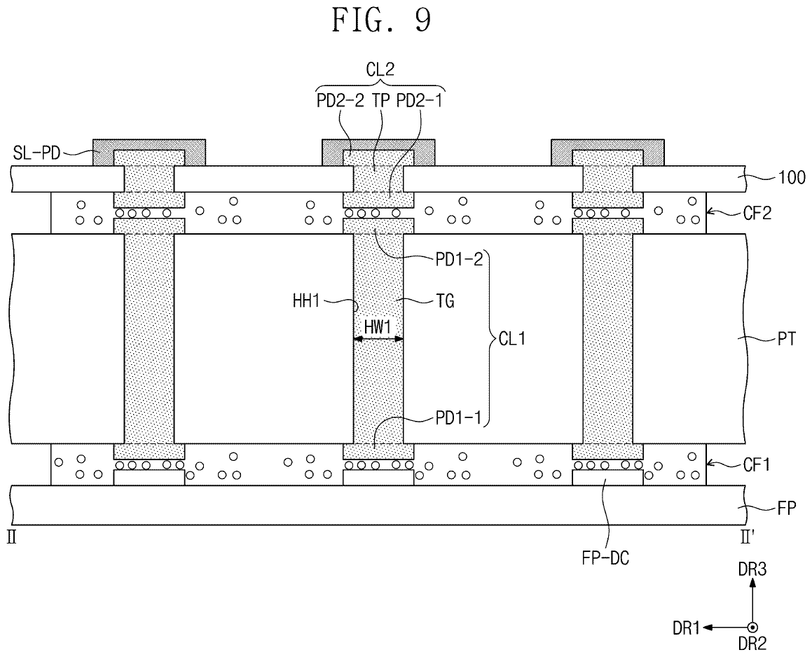

FIG. 7 is a cross-sectional view of a portion of the display module DM taken along a line I-I′ of FIG. 5. FIG. 8 is an enlarged view of an area AA′ of FIG. 7. FIG. 9 is a cross-sectional view of a portion of the display module taken along a line II-II′ of FIG. 5.

Hereinafter, a connection path between the circuit board FPCB and the signal lines SL will be described with reference to FIGS. 7 to 9.

Each of the signal lines SL may include the line part SL-N and the signal pad SL-PD. One side of each of the signal lines SL may be connected to the pixel PX (refer to FIG. 5), and the other side of each of the signal lines SL may be connected to a second line CL2. That is, the line part SL-N corresponding to the one side may be connected to the pixel PX (refer to FIG. 5), and the signal pad SL-PD corresponding to the other side may be connected to the second line CL2. The signal lines SL may be connected to the circuit board FPCB through the second lines CL2 and first lines CL1.

Referring to FIGS. 7 and 8, the display module DM may include a pad area PA defined in the second non-folding area NFA2.

In the present disclosure, the pad area PA may be defined as an area in which the signal pad SL-PD is disposed when viewed in the plane.

The base substrate 100 may include an overlap portion 100-1 and a protrusion portion 100-2. However, in the present disclosure, the overlap portion 100-1 and the protrusion portion 100-2 are merely distinguished for the sake of convenience in explanation, and the base substrate 100 may be provided as a single unit.

The protrusion portion 100-2 may be protruded outwardly by about 0.01 mm or more and about 1 mm or less with respect to an end RE of the resin layer RL, which is adjacent to the first holes HH1. The overlap portion 100-1 may extend inwardly with respect to the end RE and may overlap the resin layer RL.

The protrusion portion 100-2 may be provided with the second holes HH2 defined through an upper surface and a rear surface thereof.

When viewed in the plane, the second holes HH2 may overlap the first holes HH1.

The first and second holes HH1 and HH2 may be openings with a circular shape when viewed in the plane as shown in FIG. 3, however, the shape of the first and second holes HH1 and HH2 should not be limited thereto or thereby.

The second lines CL2 may be disposed in the second holes HH2. Each of the second lines CL2 may include a second-first pad PD2-1 exposed without being covered by a rear surface of the protrusion portion 100-2, a second-second pad PD2-2 exposed without being covered by an upper surface of the protrusion portion 100-2, and a second connection portion TP disposed between the second-first pad PD2-1 and the second-second pad PD2-2. However, they are distinguished for the convenience of explanation, and each of the second lines CL2 may be provided as a single unit.

The second lines CL2 may be in contact with the signal pad SL-PD. In detail, the second lines CL2 may be directly in contact with the signal pad SL-PD. That is, when the second lines CL2 are formed in the second holes HH2 and the signal line SL is formed on the second lines CL2 and the base substrate 100 through a deposition process, the signal pad SL-PD may be directly formed on the second-second pad PD2-2.

Each of the first holes HH1 may be defined through an upper surface PU and a rear surface PB of the plate PT. The first lines CL1 may be disposed in the first holes HH1.

Each of the first lines CL1 may include a first-first pad PD1-1 exposed without being covered by the rear surface PB of the plate PT, a first-second pad PD1-2 exposed without being covered by the upper surface PU of the plate PT, and a first connection portion TG disposed between the first-first pad PD1-1 and the first-second pad PD1-2. However, they are distinguished merely for the convenience of explanation, and each of the first lines CL1 may be provided as a single unit.

The first holes HH1 and the first lines CL1 may be formed through the through-glass via (TGV) formation process. As an example, the plate PT may be etched using a laser beam to form openings, and a conductive material may be filled in the openings. In detail, the first holes HH1 that penetrate through the upper surface PU and the rear surface PB of the plate PT are formed using the laser beam, and the conductive material for the first lines CL1 may be filled in the first holes HH1.

Accordingly, the openings defined as the first holes HH1 may be precisely formed. When viewed in a cross-section, each of the first holes HH1 may have a width HW1 equal to or greater than about 10 um and equal to or smaller than about 100 um.

The circuit board FPCB may include a substrate film FP and a driving circuit DC. The circuit board FPCB may further include a substrate pad FP-PD disposed on the substrate film FP. The driving circuit DC may be connected to the substrate pad FP-PD via a conductive line DCL included in the substrate film FP.

The display module DM according to the present embodiment may further include a first conductive film CF1 disposed between the plate PT and the circuit board FPCB and a second conductive film CF2 disposed between the base substrate 100 and the plate PT.

In the present embodiment, each of the first and second conductive films CF1 and CF2 may be an anisotropic conductive film (ACF). Each of the first and second conductive films CF1 and CF2 may include a conductive ball CB and an adhesive resin AR.

The second-first pad PD2-1 and the first-second pad PD1-2 may be pressed against each other with the second conductive film CF2 interposed therebetween, and thus, the second-first pad PD2-1 and the first-second pad PD1-2 may be connected to each other. The first-first pad PD1-1 and the substrate pad FP-PD may be pressed against each other with the first conductive film CF1 interposed therebetween, and thus, the first-first pad PD1-1 and the substrate pad FP-PD may be connected to each other.

Referring to FIGS. 7 and 8, the driving circuit DC may be connected to a corresponding pixel through the substrate film FP, the first lines CL1, the second lines CL2, and the signal lines SL. Accordingly, although the circuit board FPCB is disposed on the rear surface of the plate PT, electrical signals generated by the driving circuit DC may be applied to the pixel PX (refer to FIG. 5) or the transistor TR (refer to FIG. 6), which corresponds to the driving circuit DC.

As described above, when the circuit board FPCB is disposed on the rear surface of the display module DM, the non-display area DP-NDA (refer to FIG. 3) of the electronic device ED (refer to FIG. 1A) may be reduced.

Referring FIG. 9, the signal pads SL-PD may be connected to corresponding second lines CL2, respectively, the second lines CL2 may be connected to corresponding first lines CL1, respectively, and the first lines CL1 may be connected to the substrate film FP through the substrate pads FP-PD.

The display module DM according to the present embodiment may further include an adhesive layer disposed between the plate PT and the circuit board FPCB. The adhesive layer PSL may include a pressure sensitive adhesive material. The circuit board FPCB may be attached to the rear surface PB of the plate PT through the adhesive layer PSL.

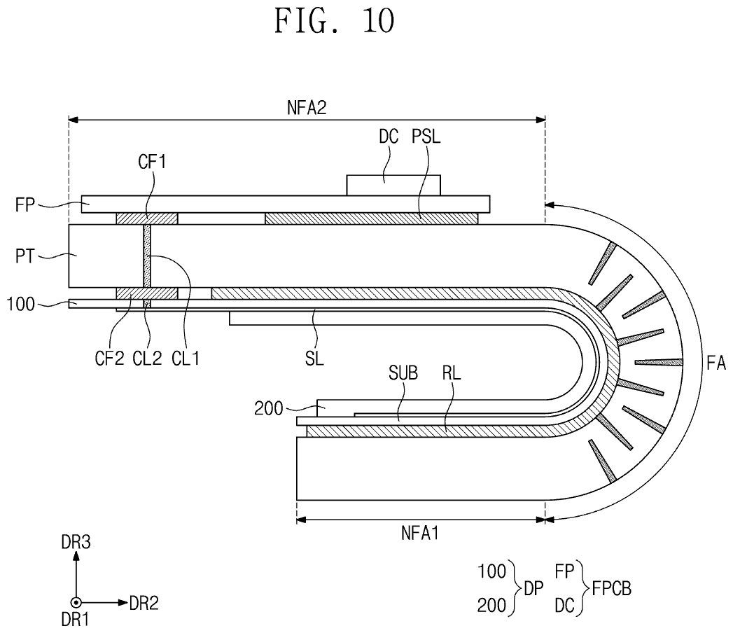

In the present embodiment, the plate PT may include the pattern portion PP, the first flat portion FP1, and the second flat portion FP2. The pattern portion PP of the plate PT may have a modulus lower than that of the flat portions FP1 and FP2 of the plate PT. This will be described in detail with reference to FIGS. 10 and 11.

FIG. 10 is a cross-sectional view of the folded state of the display module according to an embodiment of the present disclosure. FIG. 11 is a cross-sectional view of the pattern portion included in the display module according to an embodiment of the present disclosure.

Referring to FIG. 10, the circuit board FPCB may not be bent even in the folded state. Accordingly, the circuit board FPCB may maintain its shape, and thus, cracks may be prevented from occurring. In addition, the circuit board FPCB may be prevented from being separated from the display panel DP.

Referring to FIG. 11, a groove pattern GP may be defined in the pattern portion PP by recessing at least a portion of the upper surface PU or the rear surface PB of the pattern portion PP.

The pattern portion PP may include a resin portion RP filled in the groove pattern GP. Therefore, the pattern portion PP may have the modulus lower than that of the flat portions FP1 and FP2. As an example, the pattern portion PP may have the modulus equal to or greater than about 10 MPa and equal to or smaller than about 1 GPa. In detail, the pattern portion PP may have the modulus equal to or greater than about 20 MPa and equal to or smaller than about 1 GPa. In the present disclosure, the modulus of the pattern portion PP may be evaluated using a 2-point bending (2 PB) method. Accordingly, the separation between the display panel DP and the circuit board FPCB may be prevented from occurring when the display panel DP and the plate PT are folded together.

In the present embodiment, the groove pattern GP may include a first groove pattern GPa defined by recessing a portion of the upper surface PU of the pattern portion PP and a second groove pattern GPb defined by recessing a portion of the rear surface PB of the pattern portion PP.

When viewed in the cross-section, the first groove pattern GPa may have a width that decreases as it extends from the upper surface PU of the pattern portion to the rear surface PB of the pattern portion. In addition, the second groove pattern GPb may have a width that decreases as it extends from the rear surface PB of the pattern portion to the upper surface PU of the pattern portion. A side surface of the plate PT defining the groove pattern GP in a cross section may have a tapered shape that becomes narrower in a direction from the rear surface PB toward the upper surface PU.

The resin portion RP may be filled in the groove pattern GP. The resin portion RP may include a second resin. The second resin may include a synthetic resin material. As an example, the second resin may include at least one of a urethane-based resin, an epoxy-based resin, a polyester-based resin, a polyether-based resin, an acrylate-based resin, an acrylonitrile-butadiene-styrene (ABS) resin, and a rubber. In detail, the second resin may include at least one of phenylene, polyethylene terephthalate (PET), polyimide (PI), polyamide (PAI), polyethylene naphthalate (PEN), and polycarbonate (PC).

The second resin may include a material having substantially the same refractive index as that of the pattern portion PP. Accordingly, a light traveling to the resin portion RP and the pattern portion PP may not be refracted at a boundary between the resin portion RP and the pattern portion PP. Therefore, the boundary between the resin portion RP and the pattern portion PP may not be viewed by the user.

In a conventional foldable electronic device, when a modulus of an adhesive layer used to attach a display panel and a plate is low, a circuit board is separated or cracks occur during a folding process, and when the modulus of the adhesive layer is high, a buckling phenomenon occurs between the display panel and the plate.

Unlike the conventional foldable electronic device, the electronic device ED according to non-limiting embodiments of the present disclosure optimizes the material for the plate PT, the position of the circuit board FPCB, and the modulus of the resin layer RL thereby preventing cracks and/or a buckling phenomenon that is known to occur.

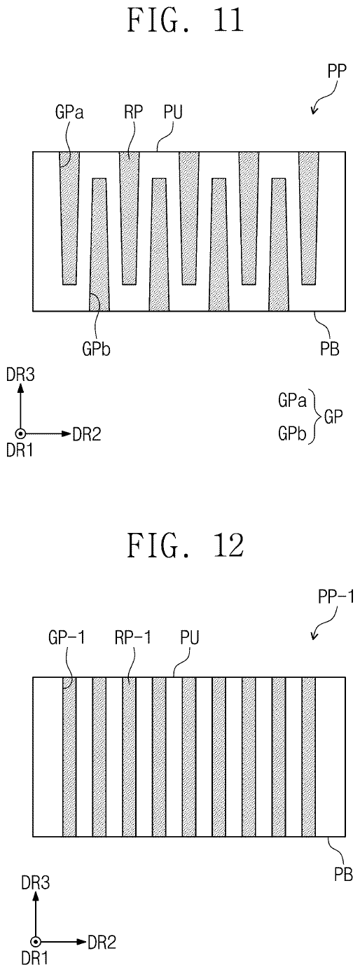

FIGS. 12 to 14 are cross-sectional views of pattern portions included in the display module according to embodiments of the present disclosure.

In FIGS. 12 to 14, the same/similar reference numerals denote the same/similar elements in FIG. 11, and thus, detailed descriptions of the same elements will be omitted.

Referring to FIG. 12, a pattern portion PP-1 may include a groove pattern portion GP-1 defined to completely penetrate through an upper surface PU and a rear surface PB thereof. In the present embodiment, the groove pattern portion GP-1 may be provided in plural, and the groove pattern portions GP-1 may be arranged spaced apart from each other at a predetermined distance.

A resin portion RP-1 including a first resin may be disposed in each of the groove pattern portions GP-1.

Referring to FIG. 13, a pattern portion PP-2 may include a groove pattern portion GP-2 defined by upwardly recessing a portion of a rear surface PB toward an upper surface PU thereof.

In the present embodiment, the groove pattern portion GP-2 may be defined by a groove flat portion GF and first groove inclination portions GS-1 spaced apart from each other with the groove flat portion GF interposed therebetween and inclined toward the groove flat portion GF.

A resin portion RP-2 including a first resin may be disposed in the groove pattern portion GP-2.

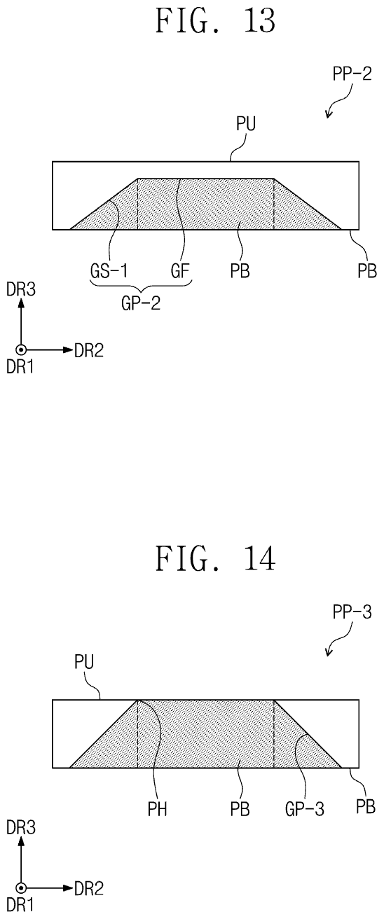

Referring to FIG. 14, a pattern portion PP-3 may include a groove pattern portion GP-3 defined to completely penetrate through an upper surface PU and a rear surface PB thereof. A side surface of the pattern portion PP-3, which defines the groove pattern portion GP-3, may be inclined in a direction toward an opening formed through the upper surface PU. That is, when viewed in the plane, a pattern hole PH may be defined through the upper surface of the pattern portion PP-3, and the side surface of the pattern portion PP-3, which defines the groove pattern portion GP-3, may be inclined in a direction toward the pattern hole PH.

A resin portion RP-3 including a first resin may be disposed in the groove pattern portion GP-3. The resin portion RP-3 may have a trapezoidal shape with a lower side longer than an upper side when viewed in the cross-section.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims.

What is claimed is:

1. An electronic device comprising:
a display panel comprising a folding area defined therein and first and second non-folding areas defined therein and spaced apart from each other with the folding area interposed therebetween and comprising pixels and signal lines connected to the pixels;
a plate disposed under the display panel and comprising a pattern portion overlapping the folding area, a first flat portion overlapping the first non-folding area, and a second flat portion overlapping the second non-folding area and provided with first holes defined through an upper surface and a rear surface thereof;
first lines disposed in the first holes and connected to the signal lines; and
a circuit board connected to the signal lines via the first lines and disposed under the plate.

2. The electronic device of claim 1, wherein the plate is non-conductive and comprises a glass material.

3. The electronic device of claim 1, wherein the plate has a thickness equal to or greater than about 70 micrometers and equal to or smaller than about 400 micrometers.

4. The electronic device of claim 1, wherein the display panel further comprises:
a base substrate that comprises polyimide (PI) and is provided with second holes defined through upper and rear surfaces thereof and overlapping the first holes; and
second lines disposed in the second holes.

5. The electronic device of claim 4, wherein each of the first lines further comprises a first-first pad exposed without being covered by the rear surface of the plate and a first-second pad exposed without being covered by the upper surface of the plate, and each of the second lines further comprises a second-first pad exposed without being covered by the rear surface of the base substrate and a second-second pad exposed without being covered by the upper surface of the base substrate.

6. The electronic device of claim 4, further comprising:
a first conductive film disposed between the circuit board and the plate; and
a second conductive film disposed between the plate and the base substrate.

7. The electronic device of claim 6, wherein one ends of the signal lines are connected to the pixels, the other ends of the signal lines are connected to the second lines, and the signal lines are connected to the circuit board via the second lines and the first lines.

8. The electronic device of claim 1, wherein each of the first holes has a width equal to or greater than about 10 micrometers and equal to or smaller than about 100 micrometers when viewed in a cross-section.

9. The electronic device of claim 1, further comprising a resin layer disposed between the plate and the display panel and comprising a first resin having a modulus equal to or greater than about 1 MPa and equal to or smaller than about 5 GPa.

10. The electronic device of claim 9, wherein the resin layer has a thickness equal to or greater than about 5 micrometers and equal to or smaller than about 20 micrometers.

11. The electronic device of claim 10, wherein the display panel further comprises a base substrate, and the base substrate comprises a protrusion portion protruding outward by about 0.01 mm or more and about 1 mm or less with respect to an end of the resin layer, which is adjacent to the first holes, and an overlap portion extending inward from the protrusion portion and overlapping the resin layer.

12. The electronic device of claim 1, further comprising an adhesive layer disposed between the circuit board and the plate and comprising a pressure sensitive adhesive material, wherein the circuit board is attached to the rear surface of the plate by the adhesive layer.

13. The electronic device of claim 1, wherein the pattern portion comprises a groove pattern defined by recessing a portion of the upper surface and at least a portion of the rear surface, the plate further comprises a resin portion filled in the groove pattern and comprising a second resin, and the pattern portion has a modulus equal to or greater than about 10 MPa and equal to or smaller than about 1 GPa.

14. The electronic device of claim 13, wherein the groove pattern is defined in plural, and at least a portion of the groove patterns is defined to completely penetrate through the upper and rear surfaces of the plate.

15. The electronic device of claim 13, wherein the groove pattern is defined by a groove flat portion and groove inclination portions spaced apart from each other and inclined in a direction toward the groove flat portion.

16. The electronic device of claim 13, wherein the groove pattern is defined through the upper and rear surfaces, and a side surface of the plate, which defines the groove pattern when viewed in a cross-section, has a tapered shape that becomes gradually narrower from the rear surface to the upper surface.

17. The electronic device of claim 1, wherein the circuit board comprises a substrate film and a driving circuit disposed on the substrate film.

18. The electronic device of claim 1, further comprising:
a ultra-thin glass layer disposed on the display panel; and
a protective layer disposed on the ultra-thin glass layer.

19. The electronic device of claim 18, further comprising an impact absorbing layer disposed between the ultra-thin glass layer and the display panel and comprising polyethylene terephthalate (PET).

20. The electronic device of claim 1, wherein the plate has a thickness greater than a thickness of the display panel, and the pattern portion has a modulus equal to or greater than about 20 MPa and equal to or smaller than about 1 GPa.
